(19) United States
(12) Patent Application Publication
(10) Pub. No.: US 2025/0391491 A1
(43) Pub. Date: Dec. 25, 2025

(54) ERROR CORRECTION CONFIGURATIONS FOR MEMORY SYSTEMS

(71) Applicant: Micron Technology, Inc., Boise, ID (US)

(72) Inventors: Amiya Banerjee, Bangalore (IN); Jameer Mulani, Bangalore (IN); Prasad Bylahalli Chandrashekara, Bangalore (IN)

(21) Appl. No.: 19/239,416

(22) Filed: Jun. 16, 2025

Related U.S. Application Data
(60) Provisional application No. 63/663,590, filed on Jun. 24, 2024.

(51) Int. Cl. G11C 29/52; G11C 16/26; G11C 16/34

(52) U.S. Cl. CPC G11C 29/52; G11C 16/26; G11C 16/3418

(57) ABSTRACT

Methods, systems, and devices for error correction configurations for memory systems are described. The described techniques provide for a memory system to evaluate one or more additional conditions when determining whether to initiate a refresh operation. For example, the memory system may determine whether the bit error rate (BER) of a page of memory cells satisfies a lower bound threshold corresponding to the BER threshold that triggers a refresh operation, and an upper bound threshold indicative of a BER at which a refresh operation may be prioritized. If the BER of a page is within the range of threshold values, the memory system may generate one or more additional layers of encoding associated with the page and may postpone the refresh operation for a duration.

### CROSS REFERENCE

The present Application for Patent claims priority to U.S. Patent Application No. 63/663,590 by Banerjee et al., entitled “ERROR CORRECTION CONFIGURATIONS FOR MEMORY SYSTEMS,” filed Jun. 24, 2024, which is assigned to the assignee hereof, and which is expressly incorporated by reference in its entirety herein.

### TECHNICAL FIELD

The following relates to one or more systems for memory, including error correction configurations for memory systems.

### BACKGROUND

Memory devices are widely used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored. To access the stored information, the memory device may read (e.g., sense, detect, retrieve, determine) states from the memory cells. To store information, the memory device may write (e.g., program, set, assign) states to the memory cells.

Various types of memory devices exist, including magnetic hard disks, random access memory (RAM), read-only memory (ROM), dynamic RAM (DRAM), synchronous dynamic RAM (SDRAM), static RAM (SRAM), ferroelectric RAM (FeRAM), magnetic RAM (MRAM), resistive RAM (RRAM), flash memory, phase change memory (PCM), self-selecting memory, chalcogenide memory technologies, not-or (NOR) and not-and (NAND) memory devices, and others. Memory cells may be described in terms of volatile configurations or non-volatile configurations. Memory cells configured in a non-volatile configuration may maintain stored logic states for extended periods of time even in the absence of an external power source. Memory cells configured in a volatile configuration may lose stored states when disconnected from an external power source.

### BRIEF DESCRIPTION OF THE DRAWINGS

FIG. 1 shows an example of a system that supports error correction configurations for memory systems in accordance with examples as disclosed herein.

FIG. 2 shows an example of a process that supports error correction configurations for memory systems in accordance with examples as disclosed herein.

FIG. 3 shows a block diagram of a memory system that supports error correction configurations for memory systems in accordance with examples as disclosed herein.

FIG. 4 shows a flowchart illustrating a method or methods that support error correction configurations for memory systems in accordance with examples as disclosed herein.

### DETAILED DESCRIPTION

Memory systems may perform one or more operations associated with maintaining the integrity of stored information, which may include correcting one or more errors in an array of memory cells (e.g., a block, which may include multiple pages of memory cells). For example, a memory system may initiate a refresh operation when a bit-error-rate (BER) (e.g., indicative of a quantity of errors in data stored to the array) of an array of memory cells satisfies a threshold value. Such refresh operations may include the memory system transferring the data from an initial block to another block (e.g., a fresh block) of memory cells of the memory system. In some examples, the memory system may prioritize performing the refresh operation on a block once the memory system determines that a BER of a page included in the block satisfies the threshold, which may correspond to an error correction capability of a controller of the memory system (e.g., the memory system may prioritize refresh operations to prevent uncorrectable errors).

However, in some scenarios, prioritizing a refresh operation may not be desirable. For example, performing a refresh operation may be inopportune when the memory system is outside a normal temperature range (e.g., causing additional write amplification (WA)), when the memory system powers on after being powered off for a relatively long duration (e.g., causing latency associated with refresh a large quantity of blocks), when a relatively small percentage of word lines of the memory system have the relatively high BER, or any combination thereof, among other examples. Such adverse effects may reduce an overall performance of the memory system.

To support postponing refresh operations while avoiding loss of data integrity, a memory system may evaluate one or more additional conditions when determining whether to initiate a refresh operation. For example, the memory system may determine whether the BER of a page of memory cells satisfies a range of threshold values. In some cases, the range of threshold values may include a lower bound threshold corresponding to the BER threshold that triggers a refresh operation (e.g., associated with the error correction capability of the memory system) and an upper bound threshold. The upper bound threshold may be referred to as a ‘relaxed’ threshold for refresh operations, and may be indicative of a BER at which a refresh operation should be performed (e.g., prioritized) for a block (e.g., regardless of other conditions). If the memory system determines that a BER of a page is within the range of threshold values (e.g., a page suitable for refresh that does not trigger a prioritized refresh), the memory system may generate one or more additional layers of encoding (e.g., additional error correction code (ECC) bits generated in addition to a default quantity of ECC bits generated when the data is stored to the page) to improve the error correction capability for the page. In some examples, the memory system may postpone the refresh operation for a duration, which may indicate a time between identifying the BER within the range of threshold values and a condition of the memory system being satisfied.

For example, the condition may be an environmental condition, such as a temperature of the memory system (e.g., the refresh may be postponed until the memory system is in a relatively normal or acceptable temperature range), or a performance condition, such as an operational state of the memory system (e.g., the refresh may be postponed until the memory system is in a performant and/or idle state), or a threshold quantity of word lines showing relatively high BER. In some examples, the memory system may store the additional layers of encoding to a buffer and may flush the data from the buffer to non-volatile memory (e.g., single-level cell (SLC) blocks) once the data reaches a threshold size, which may correspond to a programming page size (e.g., 16 KB or 4 KB for partial-page programming). Such techniques may reduce adverse effects such as WA or latency associated with forcing refresh operations while mitigating loss of data integrity, thereby improving memory system performance.

In addition to applicability in memory systems as described herein, techniques for error correction configurations may be generally implemented to improve the performance of various electronic devices and systems (including artificial intelligence (AI) applications, augmented reality (AR) applications, virtual reality (VR) applications, and gaming). Some electronic device applications, including high-performance applications such as AI, AR, VR, and gaming, may be associated with relatively high processing requirements to satisfy user expectations. As such, increasing processing capabilities of the electronic devices by decreasing response times, improving power consumption, reducing complexity, increasing data throughput or access speeds, decreasing communication times, or increasing memory capacity or density, among other performance indicators, may improve user experience or appeal. Implementing the techniques described herein may improve the performance of electronic devices by reducing an impact of prioritized refresh operations when such refresh operations may otherwise be postponed, which may improve response times and resource utilization at an electronic device, among other benefits.

Features of the disclosure are illustrated and described in the context of systems, devices, and circuits. Features of the disclosure are further illustrated and described in the context of flowcharts.

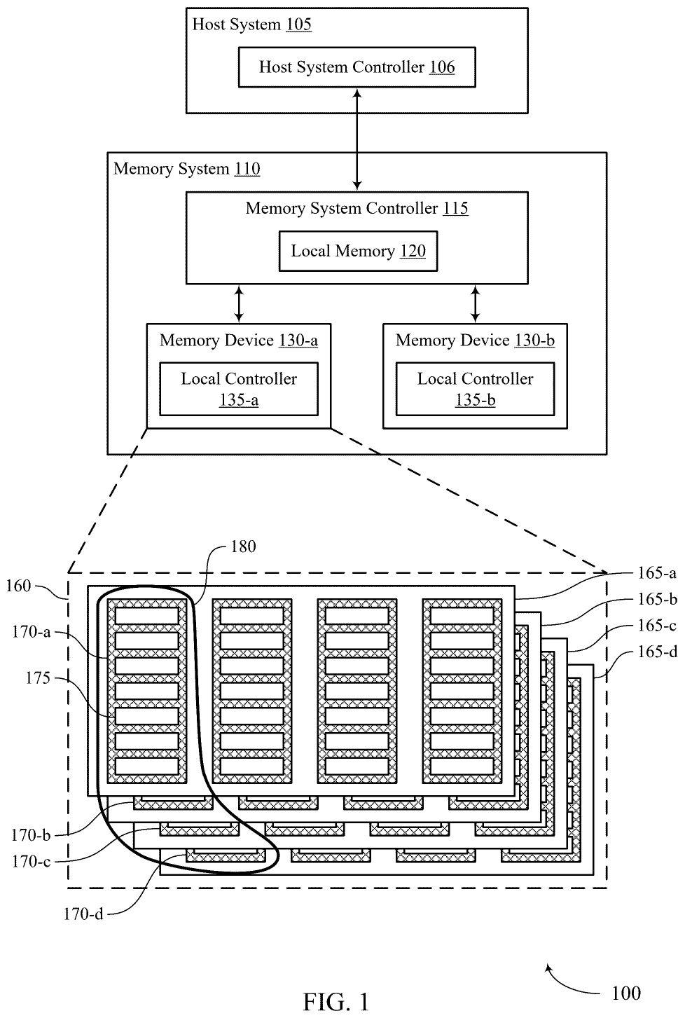

FIG. 1 shows an example of a system 100 that supports error correction configurations for memory systems in accordance with examples as disclosed herein. The system 100 includes a host system 105 coupled with a memory system 110. The system 100 may be included in a computing device such as a desktop computer, a laptop computer, a network server, a mobile device, a vehicle, an Internet of Things (IoT) enabled device, an embedded computer (e.g., one included in a vehicle, industrial equipment, or a networked commercial device), or any other computing device that includes memory and a processing device.

A memory system 110 may be or include any device or collection of devices, where the device or collection of devices includes at least one memory array. For example, a memory system 110 may be or include a Universal Flash Storage (UFS) device, an embedded Multi-Media Controller (eMMC) device, a flash device, a universal serial bus (USB) flash device, a secure digital (SD) card, a solid-state drive (SSD), a hard disk drive (HDD), a dual in-line memory module (DIMM), a small outline DIMM (SO-DIMM), or a non-volatile DIMM (NVDIMM), among other devices.

The system 100 may include a host system 105, which may be coupled with the memory system 110. In some examples, this coupling may include an interface with a host system controller 106, which may be an example of a controller or control component configured to cause the host system 105 to perform various operations in accordance with examples as described herein. The host system 105 may include one or more devices and, in some cases, may include a processor chipset and a software stack executed by the processor chipset. For example, the host system 105 may include an application configured for communicating with the memory system 110 or a device therein. The processor chipset may include one or more cores, one or more caches (e.g., memory local to or included in the host system 105), a memory controller (e.g., NVDIMM controller), and a storage protocol controller (e.g., peripheral component interconnect express (PCIe) controller, serial advanced technology attachment (SATA) controller). The host system 105 may use the memory system 110, for example, to write data to the memory system 110 and read data from the memory system 110. Although one memory system 110 is shown in FIG. 1, the host system 105 may be coupled with any quantity of memory systems 110.

The host system 105 may be coupled with the memory system 110 via at least one physical host interface. The host system 105 and the memory system 110 may, in some cases, be configured to communicate via a physical host interface using an associated protocol (e.g., to exchange or otherwise communicate control, address, data, and other signals between the memory system 110 and the host system 105). Examples of a physical host interface may include, but are not limited to, a SATA interface, a UFS interface, an eMMC interface, a PCIe interface, a USB interface, a Fiber Channel interface, a Small Computer System Interface (SCSI), a Serial Attached SCSI (SAS), a Double Data Rate (DDR) interface, a DIMM interface (e.g., DIMM socket interface that supports DDR), an Open NAND Flash Interface (ONFI), and a Low Power Double Data Rate (LPDDR) interface. In some examples, one or more such interfaces may be included in or otherwise supported between a host system controller 106 of the host system 105 and a memory system controller 115 of the memory system 110. In some examples, the host system 105 may be coupled with the memory system 110 (e.g., the host system controller 106 may be coupled with the memory system controller 115) via a respective physical host interface for each memory device 130 included in the memory system 110, or via a respective physical host interface for each type of memory device 130 included in the memory system 110.

The memory system 110 may include a memory system controller 115 and one or more memory devices 130. A memory device 130 may include one or more memory arrays of any type of memory cells (e.g., non-volatile memory cells, volatile memory cells, or any combination thereof). Although two memory devices 130-a and 130-b are shown in the example of FIG. 1, the memory system 110 may include any quantity of memory devices 130. Further, if the memory system 110 includes more than one memory device 130, different memory devices 130 within the memory system 110 may include the same or different types of memory cells.

The memory system controller 115 may be coupled with and communicate with the host system 105 (e.g., via the physical host interface) and may be an example of a controller or control component configured to cause the memory system 110 to perform various operations in accordance with examples as described herein. The memory system controller 115 may also be coupled with and communicate with memory devices 130 to perform operations such as reading data, writing data, erasing data, or refreshing data at a memory device 130—among other such operations-which may generically be referred to as access operations. In some cases, the memory system controller 115 may receive commands from the host system 105 and communicate with one or more memory devices 130 to execute such commands (e.g., at memory arrays within the one or more memory devices 130). For example, the memory system controller 115 may receive commands or operations from the host system 105 and may convert the commands or operations into instructions or appropriate commands to achieve the desired access of the memory devices 130. In some cases, the memory system controller 115 may exchange data with the host system 105 and with one or more memory devices 130 (e.g., in response to or otherwise in association with commands from the host system 105). For example, the memory system controller 115 may convert responses (e.g., data packets or other signals) associated with the memory devices 130 into corresponding signals for the host system 105.

The memory system controller 115 may be configured for other operations associated with the memory devices 130. For example, the memory system controller 115 may execute or manage operations such as wear-leveling operations, garbage collection operations, error control operations such as error-detecting operations or error-correcting operations, encryption operations, caching operations, media management operations, background refresh, health monitoring, and address translations between logical addresses (e.g., logical block addresses (LBAs)) associated with commands from the host system 105 and physical addresses (e.g., physical block addresses) associated with memory cells within the memory devices 130.

The memory system controller 115 may include hardware such as one or more integrated circuits or discrete components, a buffer memory, or a combination thereof. The hardware may include circuitry with dedicated (e.g., hard-coded) logic to perform the operations ascribed herein to the memory system controller 115. The memory system controller 115 may be or include a microcontroller, special purpose logic circuitry (e.g., a field programmable gate array (FPGA), an application specific integrated circuit (ASIC), a digital signal processor (DSP)), or any other suitable processor or processing circuitry.

The memory system controller 115 may also include a local memory 120. In some cases, the local memory 120 may include read-only memory (ROM) or other memory that may store operating code (e.g., executable instructions) executable by the memory system controller 115 to perform functions ascribed herein to the memory system controller 115. In some cases, the local memory 120 may additionally, or alternatively, include static random access memory (SRAM) or other memory that may be used by the memory system controller 115 for internal storage or calculations, for example, related to the functions ascribed herein to the memory system controller 115. Additionally, or alternatively, the local memory 120 may serve as a cache for the memory system controller 115. For example, data may be stored in the local memory 120 if read from or written to a memory device 130, and the data may be available within the local memory 120 for subsequent retrieval for or manipulation (e.g., updating) by the host system 105 (e.g., with reduced latency relative to a memory device 130) in accordance with a cache policy.

Although the example of the memory system 110 in FIG. 1 has been illustrated as including the memory system controller 115, in some cases, a memory system 110 may not include a memory system controller 115. For example, the memory system 110 may additionally, or alternatively, rely on an external controller (e.g., implemented by the host system 105) or one or more local controllers 135, which may be internal to memory devices 130, respectively, to perform the functions ascribed herein to the memory system controller 115. In general, one or more functions ascribed herein to the memory system controller 115 may, in some cases, be performed instead by the host system 105, a local controller 135, or any combination thereof. In some cases, a memory device 130 that is managed at least in part by a memory system controller 115 may be referred to as a managed memory device. An example of a managed memory device is a managed NAND (MNAND) device.

A memory device 130 may include one or more arrays of non-volatile memory cells. For example, a memory device 130 may include NAND (e.g., NAND flash) memory, ROM, phase change memory (PCM), self-selecting memory, other chalcogenide-based memories, ferroelectric random access memory (FeRAM), magneto RAM (MRAM), NOR (e.g., NOR flash) memory, Spin Transfer Torque (STT)-MRAM, conductive bridging RAM (CBRAM), resistive random access memory (RRAM), oxide based RRAM (OxRAM), electrically erasable programmable ROM (EEPROM), or any combination thereof. Additionally, or alternatively, a memory device 130 may include one or more arrays of volatile memory cells. For example, a memory device 130 may include RAM memory cells, such as dynamic RAM (DRAM) memory cells and synchronous DRAM (SDRAM) memory cells.

In some examples, a memory device 130 may include (e.g., on the same die, within the same package) a local controller 135, which may execute operations on one or more memory cells of the respective memory device 130. A local controller 135 may operate in conjunction with a memory system controller 115 or may perform one or more functions ascribed herein to the memory system controller 115. For example, as illustrated in FIG. 1, a memory device 130-a may include a local controller 135-a and a memory device 130-b may include a local controller 135-b.

In some cases, a memory device 130 may be or include a NAND device (e.g., NAND flash device). A memory device 130 may be or include a die 160 (e.g., a memory die). For example, in some cases, a memory device 130 may be a package that includes one or more dies 160. A die 160 may, in some examples, be a piece of electronics-grade semiconductor cut from a wafer (e.g., a silicon die cut from a silicon wafer). Each die 160 may include one or more planes 165, and each plane 165 may include a respective set of blocks 170, where each block 170 may include a respective set of pages 175, and each page 175 may include a set of memory cells.

In some cases, a NAND memory device 130 may include memory cells configured to each store one bit of information, which may be referred to as single level cells (SLCs). Additionally, or alternatively, a NAND memory device 130 may include memory cells configured to each store multiple bits of information, which may be referred to as multi-level cells (MLCs) if configured to each store two bits of information, as tri-level cells (TLCs) if configured to each store three bits of information, as quad-level cells (QLCs) if configured to each store four bits of information, or more generically as multiple-level memory cells. Multiple-level memory cells may provide greater density of storage relative to SLC memory cells but may, in some cases, involve narrower read or write margins or greater complexities for supporting circuitry.

In some cases, planes 165 may refer to groups of blocks 170 and, in some cases, concurrent operations may be performed on different planes 165. For example, concurrent operations may be performed on memory cells within different blocks 170 so long as the different blocks 170 are in different planes 165. In some cases, an individual block 170 may be referred to as a physical block, and a virtual block 180 may refer to a group of blocks 170 within which concurrent operations may occur. For example, concurrent operations may be performed on blocks 170-a, 170-b, 170-c, and 170-d that are within planes 165-a, 165-b, 165-c, and 165-d, respectively, and blocks 170-a, 170-b, 170-c, and 170-d may be collectively referred to as a virtual block 180. In some cases, a virtual block may include blocks 170 from different memory devices 130 (e.g., including blocks in one or more planes of memory device 130-a and memory device 130-b). In some cases, the blocks 170 within a virtual block may have the same block address within their respective planes 165 (e.g., block 170-a may be “block 0” of plane 165-a, block 170-b may be “block 0” of plane 165-b, and so on). In some cases, performing concurrent operations in different planes 165 may be subject to one or more restrictions, such as concurrent operations being performed on memory cells within different pages 175 that have the same page address within their respective planes 165 (e.g., related to command decoding, page address decoding circuitry, or other circuitry being shared across planes 165).

In some cases, a block 170 may include memory cells organized into rows (pages 175) and columns (e.g., strings, not shown). For example, memory cells in the same page 175 may share (e.g., be coupled with) a common word line, and memory cells in the same string may share (e.g., be coupled with) a common digit line (which may alternatively be referred to as a bit line).

For some NAND architectures, memory cells may be read and programmed (e.g., written) at a first level of granularity (e.g., at a page level of granularity, or portion thereof) but may be erased at a second level of granularity (e.g., at a block level of granularity). That is, a page 175 may be the smallest unit of memory (e.g., set of memory cells) that may be independently programmed or read (e.g., programed or read concurrently as part of a single program or read operation), and a block 170 may be the smallest unit of memory (e.g., set of memory cells) that may be independently erased (e.g., erased concurrently as part of a single erase operation). Further, in some cases, NAND memory cells may be erased before they can be re-written with new data. Thus, for example, a used page 175 may, in some cases, not be updated until the entire block 170 that includes the page 175 has been erased.

In some cases, to update some data within a block 170 while retaining other data within the block 170, the memory device 130 may copy the data to be retained to a new block 170 and write the updated data to one or more remaining pages of the new block 170. The memory device 130 (e.g., the local controller 135) or the memory system controller 115 may mark or otherwise designate the data that remains in the old block 170 as invalid or obsolete and may update a logical-to-physical (L2P) mapping table to associate the logical address (e.g., LBA) for the data with the new, valid block 170 rather than the old, invalid block 170. In some cases, such copying and remapping may be performed instead of erasing and rewriting the entire old block 170 due to latency or wearout considerations, for example. In some cases, one or more copies of an L2P mapping table may be stored within the memory cells of the memory device 130 (e.g., within one or more blocks 170 or planes 165) for use (e.g., reference and updating) by the local controller 135 or memory system controller 115.

In some cases, L2P mapping tables may be maintained and data may be marked as valid or invalid at the page level of granularity, and a page 175 may contain valid data, invalid data, or no data. Invalid data may be data that is outdated, which may be due to a more recent or updated version of the data being stored in a different page 175 of the memory device 130. Invalid data may have been previously programmed to the invalid page 175 but may no longer be associated with a valid logical address, such as a logical address referenced by the host system 105. Valid data may be the most recent version of such data being stored on the memory device 130. A page 175 that includes no data may be a page 175 that has never been written to or that has been erased.

In some cases, a memory system controller 115 or a local controller 135 may perform operations (e.g., as part of one or more media management algorithms) for a memory device 130, such as wear leveling, background refresh, garbage collection, scrub, block scans, health monitoring, or others, or any combination thereof. For example, within a memory device 130, a block 170 may have some pages 175 containing valid data and some pages 175 containing invalid data. To avoid waiting for all of the pages 175 in the block 170 to have invalid data in order to erase and reuse the block 170, an algorithm referred to as “garbage collection” may be invoked to allow the block 170 to be erased and released as a free block for subsequent write operations. Garbage collection may refer to a set of media management operations that include, for example, selecting a block 170 that contains valid and invalid data, selecting pages 175 in the block that contain valid data, copying the valid data from the selected pages 175 to new locations (e.g., free pages 175 in another block 170), marking the data in the previously selected pages 175 as invalid, and erasing the selected block 170. As a result, the quantity of blocks 170 that have been erased may be increased such that more blocks 170 are available to store subsequent data (e.g., data subsequently received from the host system 105).

In some examples of the system 100, a memory system 110 may perform refresh operations to support correcting errors in data stored to blocks 170 of the memory system 110. For example, if the memory system 110 identifies that a BER of a page 175 of a block 170 satisfies a threshold value, the memory system 110 may initiate a refresh operation to transfer the data to another block 170 and correct erroneous data. The threshold value may correspond to an error correction capability of a memory system controller 115, and as such the memory system 110 may prioritize a refresh once the threshold is identified for a page 175 (e.g., to avoid uncorrectable errors from developing in the block 170).

However, in some scenarios, prioritizing a refresh operation may incur adverse effects at the memory system 110. For example, performing a refresh operation may be inopportune when the memory system 110 is outside a normal temperature range (e.g., incurring additional WA), when the memory system powers on after being powered off for a relatively long duration (e.g., incurring latency associated with refresh a large quantity of blocks 170), when a relatively small percentage of word lines of the memory system 110 have the relatively high BER, or any combination thereof, among other examples. Such adverse effects may reduce an overall performance of the memory system 110.

To support postponing refresh operations while avoiding loss of data integrity, a memory system 110 may evaluate one or more additional conditions when determining whether to initiate a refresh operation for a block 170. For example, the memory system may determine whether the BER of a page 175 of memory cells satisfies a range of threshold values. The range of threshold values may include a lower bound threshold corresponding to the BER threshold that triggers a refresh operation (e.g., associated with the error correction capability of the memory system 110) and an upper bound threshold. The upper bound threshold may be referred to as a ‘relaxed’ threshold for refresh operations, and may be indicative of a BER at which a refresh operation may be performed (e.g., prioritized) for a block 170 (e.g., regardless of other conditions). If the memory system 110 determines that a BER of a page is within the range of threshold values (e.g., a page suitable for refresh that does not trigger a prioritized refresh), the memory system 110 may generate one or more additional layers of encoding (e.g., additional ECC bits generated on top of a default quantity of ECC bits generated when the data is stored to the page) associated with the page 175 to improve the error correction capability for the page. In some examples, the memory system may postpone the refresh operation for a block 170 including such pages 175 for a duration, which may indicate a time between identifying the BER within the range of threshold values and a condition of the memory system 110 being satisfied.

For example, the condition may be an environmental condition, such a temperature of the memory system 110 (e.g., the refresh may be postponed until the memory system is in a relatively normal or acceptable temperature range), or may be a performance condition, such as an operational state of the memory system 110 (e.g., the refresh may be postponed until the memory system is in a performant and/or idle state) or a threshold quantity of word lines showing relatively high BER. In some examples, the memory system 110 may store the additional layers of encoding to a buffer and may flush the data from the buffer to non-volatile memory (e.g., SLC blocks) once the data reaches a threshold size, which may correspond to a programming page size (e.g., 16 KB or 4 KB for partial-page programming). Such techniques may reduce adverse effects such as WA or latency associated with forcing refresh operations while mitigating loss of data integrity, thereby improving memory system performance.

The system 100 may include any quantity of non-transitory computer readable media that support error correction configurations for memory systems. For example, the host system 105 (e.g., a host system controller 106), the memory system 110 (e.g., a memory system controller 115), or a memory device 130 (e.g., a local controller 135), or any combination thereof may include or otherwise may access one or more non-transitory computer readable media storing instructions (e.g., firmware, logic, code) for performing the functions ascribed herein to the host system 105, the memory system 110, or the memory device 130, or combination thereof. For example, such instructions, if executed by the host system 105 (e.g., by a host system controller 106), by the memory system 110 (e.g., by a memory system controller 115), or by a memory device 130 (e.g., by a local controller 135), may cause the host system 105, the memory system 110, or the memory device 130 to perform associated functions as described herein.

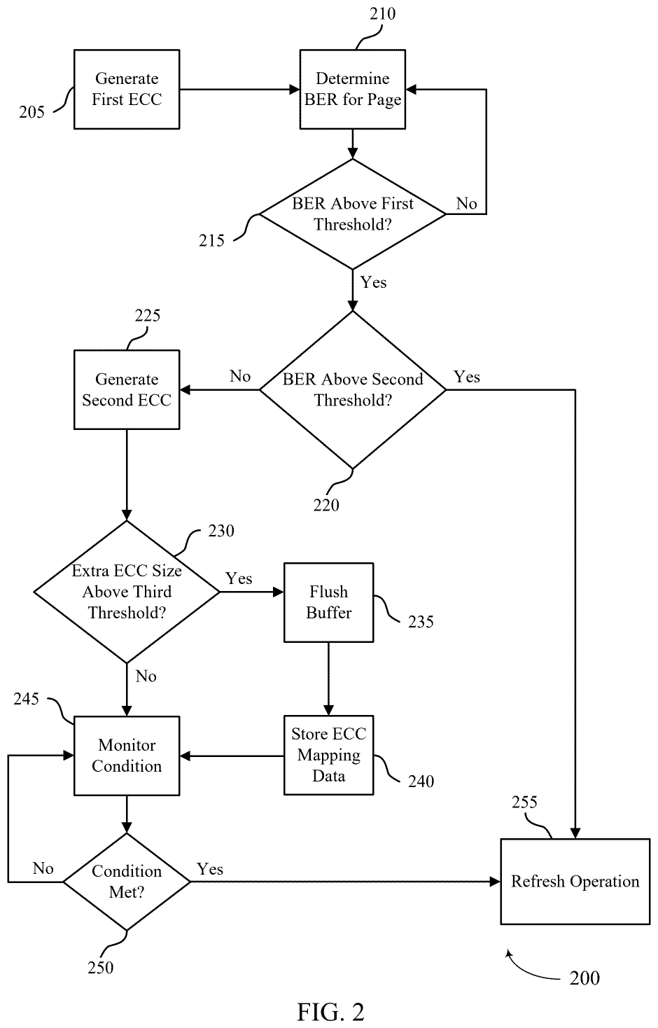

FIG. 2 shows an example of a process 200 that supports error correction configurations for memory systems in accordance with examples as disclosed herein. The process 200 may implement, or be implemented by, one or more aspects of the system 100. For example, the process 200 may show an example of a memory system determining when to perform a refresh operation for a block of memory cells, which may be examples of corresponding devices and aspects described with reference to FIG. 1.

In some cases, the process 200 may support the memory system evaluating one or more additional conditions when determining whether to initiate (e.g., prioritize) or postpone a refresh operation for a block of memory cells. For example, the memory system may determine whether a BER for a page of memory cells is within a range of threshold values and whether a condition (e.g., an environmental condition or a performance condition) of the memory system is satisfied when evaluating whether to postpone or prioritize a refresh operation.

Aspects of the process 200 may be implemented by one or more controllers, among other components. Additionally, or alternatively, aspects of the process 200 may be implemented as instructions stored in one or more memories (e.g., firmware stored in one or more memories coupled with the memory system). For example, the instructions, when executed by one or more controllers (e.g., the memory system controller 115), may cause the one or more controllers (or a device or a system) to perform the operations of the process 200. Alternative examples of the following may be implemented, where some steps are performed in a different order or not at all. Additionally, some steps may include additional features not mentioned below.

At 205, first ECC information may be generated. The ECC information may be generated by an ECC component of a memory system controller 115 of a memory system 110 as described with reference to FIG. 1. In some cases, the memory system may generate the first ECC information for a page of memory cells based on storing data to the page of memory cells. For example, the first ECC information may be an example of a default quantity of ECC bits (e.g., a first quantity of bits) generated for the page of memory cells in accordance with an error correction capability of the memory system controller. Additionally, or alternatively, the memory system may generate respective first ECC information for each page of memory cells included in a block based on storing respective data to each page of memory cells.

At 210, a BER associated with the page of memory cells may be identified. The BER associated with the page of memory cells may be identified by a memory system controller 115 as described with reference to FIG. 1. In some cases, the page of memory cells may be associated with or included in a block of the memory system that includes multiple pages of memory cells. The BER of the page may be a metric indicative of a quantity of errors in data stored to the page of memory cells and may indicate whether the block that includes the page is suitable for a refresh operation (e.g., correcting or removing the erroneous data by transferring the data stored to the block to another block).

At 215, whether the BER of the page is above a first threshold value may be determined. The memory system controller may determine whether the BER is above the first threshold value. For example, the memory system may scan the page to identify errors present in data stored to the page, which may indicate the BER of the page. In some cases, the first threshold value may correspond to a lower bound of a range of threshold BER values associated with triggering a refresh operation. For example, if the memory system identifies that the BER of the page does not satisfy the first threshold value (e.g., the BER is below the range of threshold values), the memory system may return to step 210 of the process 200 and may identify a BER of another page of memory cells included in the block (e.g., scanning a subsequent page of the block to determine whether to trigger the refresh operation for the block).

The memory system may continue to identify a BER for each page of memory cells in the block until a page satisfies at least the first threshold value or each page included in the block has been scanned (e.g., if each page of the block is associated with a BER below the range of threshold values, the memory system may not perform a refresh on the block and the process 200 may terminate). In another example, if the memory system identifies that the BER of the page satisfies the first threshold value (e.g., the BER is above the first threshold), the memory system may move to step 220 of the process 200.

At 220, whether the BER of the page is above a second threshold value may be identified. A memory system controller may determine whether the BER is above the second threshold value. In some cases, the second threshold may correspond to an upper bound of the range of threshold BER values and may be referred to as a ‘relaxed’ threshold for initiating refresh operations. If the memory system determines that the BER of the page does not satisfy the second threshold value (e.g., the BER is within the range of threshold values), the memory system may determine that the refresh operation for the block is suitable to be postponed (which may be referred to as a weak page). For example, in such cases, the memory system may determine that the BER of the page is high enough to trigger the refresh operation but is not high enough to prioritize the refresh operation (e.g., immediately), and the memory system may move to step 225 of the process 200.

At 225, second ECC information may be generated. A memory system controller may generate the second ECC information. In some cases, the second ECC information may support improved error correction capability of the memory system when correcting errors in the page of memory cells (e.g., when performing a refresh for the block including the page). In some examples, the second ECC information may include a second quantity of bits, which may be less than the first quantity of bits associated with the first ECC information. For example, second ECC information may include one or more additional layers of encoding (e.g., two additional layers, which may correspond to 32B per 4 KB codeword), which may improve error correction capabilities of a memory system controller for the page of memory cells.

Due to the page being suitable for a postponed refresh, and thus having a relatively higher risk of data loss or corruption, the additional layers of encoding may improve a read window budget (RWB) associated with the page (e.g., a 100 mV RWB improvement) to reduce or otherwise mitigate a likelihood of the controller being unable to correct errors in the data during refresh. For example, the memory system may detect an error in the data stored to the page, and may correct the error using the first ECC information and the second ECC information. In some examples, the memory system may generate the second ECC information a duration after generating the first ECC information, where the duration may correspond to a time difference between generating the first ECC information and determining that the BER of the page is within the range of threshold values (e.g., additional layers of encoding are generated in response to the refresh being postponed).

In some cases, the memory system may read the data from the page and may transfer the data to a low density parity check (LDPC) component of the memory system, which may facilitate the generation of the additional layers of encoding. The LDPC component may be included as part of or implemented separate from the memory system controller. For example, the LDPC component may include a buffer configured to store the extra ECC bits (e.g., the second ECC information) generated for pages which are suitable for postponed refresh (e.g., weak pages of the block), where the first ECC information may be stored in a same or different buffer configured to store ECC data. Additionally, or alternatively, the memory system may transmit the extra ECC bits to a host system (e.g., a host system 105 as described with reference to FIG. 1), which may store the additional layers of encoding in a host memory buffer (HMB) located at the host system.

At 230, whether a size of the extra ECC bits stored to the buffer satisfies a threshold value may be determined. The memory system controller may determine whether the size of the extra ECC bits stored to the buffer satisfies the threshold value (e.g., a third threshold value). For example, the memory system may store, in the buffer (e.g., the LDPC buffer or the HMB), additional layers of encoding for each page of the block that includes a BER within the range of threshold values until a size of the data stored to the buffer satisfies (e.g., exceeds) a threshold data size. In some cases, the threshold data size may correspond to a programming page size of the memory system (e.g., 16 KB or, in some cases, 4 KB for partial-page-programming). If, at 230, the memory system determines that the size of the data stored to the buffer satisfies the threshold data size, the memory system may move to step 235 of the process 200. Alternatively, if the memory system identifies that the size of the data stored to the buffer fails to satisfy the threshold data size, the memory system may move to step 245 of the process 200.

At 235, data stored to the buffer may be flushed. A memory system controller may transfer the data (e.g., additional layers of encoding associated with one or more weak pages of a block) from the buffer to non-volatile memory of the memory system, such as an SLC block, based on determining that the size of the data stored to the buffer satisfies the threshold data size. Such flushing may support the memory system storing additional ECC information for weak pages in relatively few blocks of memory. For example, where a relatively large quantity of pages are detected as being weak pages, the extra ECC bits for the weak pages may occupy a relatively low quantity of SLC blocks of the memory system (e.g., approximately three SLC blocks of the memory system). Additionally, such blocks may be located in any plane of the memory system and the memory system may support storing extra ECC bits in blocks at least partially storing other data.

At 240, ECC mapping data may be stored. A memory system controller may store the ECC mapping data. For example, the mapping data may indicate a relationship between the extra ECC bits generated for a respective page and the data stored to the respective page (e.g., to support the memory system identifying the additional layers of encoding when performing error correction for a page). In some cases, the memory system may store a table including the ECC mapping data to a volatile memory of the memory system, such as RAM or SRAM of the memory system. In some examples, a granularity of the mapping may correspond to a page-line, and a size of the table may be relatively small (e.g., when relatively few pages of the block are designated as weak pages).

By storing the ECC mapping data, the memory system may support accessing the additional layers of encoding when executing subsequent commands to read the data associated with the extra ECC bits. For instance, the memory system may receive a read command to read first data stored to the page of memory cells (e.g., the weak page having additional layers of encoding), and may access (e.g., concurrently access) the data and the ECC information associated with the data using the mapping information. In some examples, if the read command is associated with a sequential read operation, overhead associated with accessing the extra ECC bits may not impact the sequential read performance, since the sequential read speed may be limited by a flash interface (e.g., open NAND flash interface (ONFI)) configured for the memory system. Alternatively, if the read command is associated with a random read operation, the page storing the data and the page storing the extra ECC bits are unlikely to be the same page (e.g., less than 4% probability of being the same page), which may support the memory system reading different pages in parallel during random read operations.

At 245, a condition of the memory system may be monitored. A memory system controller may monitor the condition. For example, the memory system may monitor the condition to determine whether the condition is satisfied, which may indicate whether a refresh operation may be initiated for the block. In some cases, the condition may be an environmental condition of the memory system, a performance condition of the memory system, or both. For example, the condition may be associated with a temperature of the memory system, an operational performance of the memory system, an operational state of the memory system, a quantity of weak pages of the block, or any combination thereof.

At 250, whether the condition of the memory system is satisfied may be determined. A memory system controller may determine whether the condition is satisfied. If the memory system determines that the condition is not satisfied, the memory system may return to step 245 of the process 200 and may continue monitoring the condition. Alternatively, if the memory system determines that the condition is satisfied, the memory system may determine to initiate the refresh operation and move to step 255 of the process 200.

As an example, the memory system may determine whether a temperature associated with the memory system (e.g., an environmental condition) is within a range of threshold temperature values, which may be associated with normal operating temperatures for the memory system. For example, if the memory system identifies that the temperature is outside the range of threshold temperature values (e.g., the memory system is at a significantly cold or significantly hot temperature), the memory system may determine that the condition is not satisfied, since performing a refresh operations at an extreme temperature may incur additional write amplification at the memory system (e.g., due to performing multiple refresh operations to ensure data is correctly written at extreme temperatures).

As another example, the memory system may determine whether an operational state of the memory system (e.g., a performance condition) supports performing the refresh operation. For example, if the memory system is in a low power state (e.g., powered off) for a relatively long duration and transitions to a high power state, the memory system may identify a relatively high quantity of blocks to perform refreshes on. Performing such refreshes, however, may incur significant latency. Thus, the memory system may determine to postpone a refresh (e.g., the condition is not satisfied) after entering the high power state until the memory system is in an idle or performant state (e.g., to support performing other power-on procedures that may be otherwise interrupted by refresh operations). For example, the memory system may determine that the condition is not satisfied until the memory system is in an idle state for a threshold duration or the memory system enters a performant state.

As another example, the memory system may determine whether an operational performance of the memory system (e.g., a performance condition) satisfies a threshold value. For example, the memory system may identify whether an available bandwidth satisfies a fourth threshold value. The condition may be satisfied if the available bandwidth satisfies the fourth threshold value. As another example, the memory system may identify a quantity of weak word lines (e.g., corresponding to a quantity of pages having a respective BER that satisfies the first range of threshold values) and may determine whether the quantity of weak word lines satisfies a fifth threshold value (e.g., 10% to 15% of word lines showing relatively high BER). In some cases, if the quantity of weak word lines is relatively low and does not satisfy the fourth threshold value, the memory system may determine to postpone the refresh until the quantity of weak word lines satisfies the fourth threshold value. For example, when the quantity of weak word lines is relatively low, the memory system may identify that such word lines are inherently less suitable for storing data under stress conditions (e.g., according to characteristics of the memory system), such as frequent read disturbances, and as such the refresh may be suitable to be postponed.

In some cases, at 220, the memory system may alternatively determine that the BER of the page of memory cells is above the second threshold value. For example, the memory system may determine that the BER exceeds the upper bound of the range of threshold values, which may indicate that the page includes a significantly high BER. In such examples, the memory system may determine that the refresh operation may be prioritized (e.g., the memory system refrains from postponing the refresh) due to the BER of the page exceeding the second threshold value. For example, the memory system may determine to refresh the page using the first ECC information (e.g., without generating additional layers of encoding). In such cases, the memory system may move to step 255 of the process 200.

At 255, the refresh operation on the block including the page of memory cells may be performed. A memory system controller may perform the refresh operation. For example, the refresh operation may include transferring the data from each page of memory cells included in the block to a different block (e.g., a fresh block), which may support correcting errors in the data and increasing the integrity of the data. In some cases, if the memory system determines to postpone the refresh operation (e.g., the BER is determined to be within the range of threshold values at 210 and 215), the postponing may correspond to a duration between identifying the BER of the page at 205 and determining that the condition is met at 245. As an example, if the memory system identifies the BER of the page while the memory system is outside the normal temperature range, the duration may correspond to a time taken for the memory system to enter the normal temperature range.

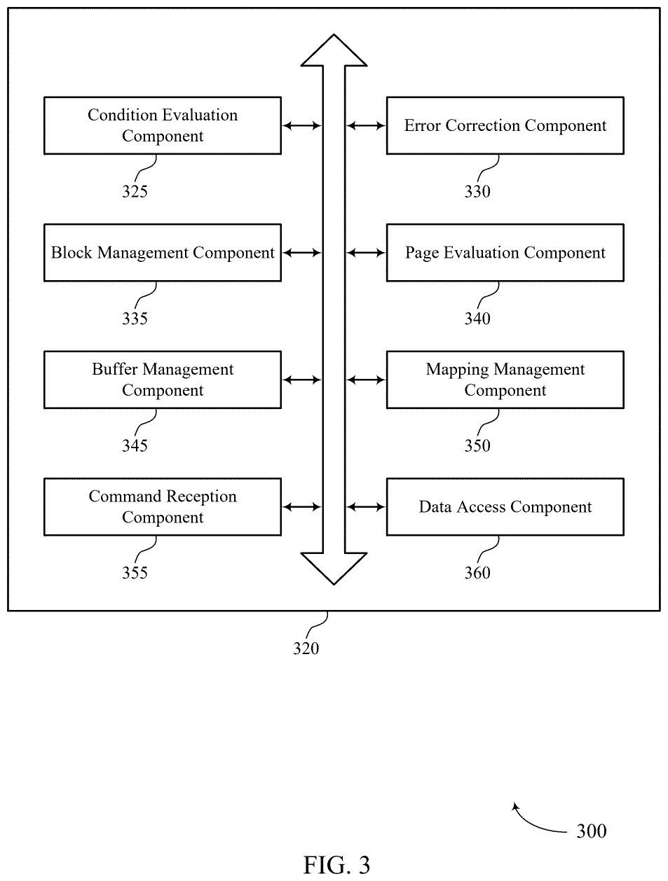

FIG. 3 shows a block diagram 300 of a memory system 320 that supports error correction configurations for memory systems in accordance with examples as disclosed herein. The memory system 320 may be an example of aspects of a memory system as described with reference to FIGS. 1 through 2. The memory system 320, or various components thereof, may be an example of means for performing various aspects of error correction configurations for memory systems as described herein. For example, the memory system 320 may include an error correction component 325, a condition evaluation component 330, a block management component 335, a page evaluation component 340, a buffer management component 345, a mapping management component 350, a command reception component 355, a data access component 360, or any combination thereof. Each of these components, or components of subcomponents thereof (e.g., one or more processors, one or more memories), may communicate, directly or indirectly, with one another (e.g., via one or more buses).

The error correction component 325 may be configured as or otherwise support a means for generating a first error correction code associated with first data in accordance with storing the first data to a first page of a block of non-volatile memory cells, where the first error correction code includes a first quantity of bits. The condition evaluation component 330 may be configured as or otherwise support a means for determining whether a condition of the memory system is satisfied in accordance with a bit error rate of the first page of non-volatile memory cells satisfying a first threshold value corresponding to a lower bound of a first range of threshold values. In some examples, the error correction component 325 may be configured as or otherwise support a means for generating a second error correction code associated with the first data in response to determining whether the condition is satisfied and the bit error rate of the first page satisfying the first threshold value, where the second error correction code includes a second quantity of bits that is less than the first quantity of bits. The block management component 335 may be configured as or otherwise support a means for postponing, for a duration, refreshing the block of non-volatile memory cells in accordance with generating the second error correction code.

In some examples, the error correction component 325 may be configured as or otherwise support a means for detecting an error in the first data. In some examples, the error correction component 325 may be configured as or otherwise support a means for correcting the error in the first data using the first error correction code and the second error correction code.

In some examples, the condition evaluation component 330 may be configured as or otherwise support a means for determining that the condition is satisfied. In some examples, the block management component 335 may be configured as or otherwise support a means for refreshing the block of non-volatile memory cells in response to determining that the condition is satisfied.

In some examples, the page evaluation component 340 may be configured as or otherwise support a means for determining that condition of the memory system is satisfied in accordance with a bit error rate of a second page of non-volatile memory cells satisfying the first threshold value, where the second page is associated with a second block of the memory system. In some examples, the block management component 335 may be configured as or otherwise support a means for refraining from postponing refreshing the second block of non-volatile memory cells for a second duration in response to determining that the condition of the memory system is satisfied. In some examples, the block management component 335 may be configured as or otherwise support a means for refreshing the second block of memory cells.

In some examples, the condition evaluation component 330 may be configured as or otherwise support a means for determining, prior to the duration, that condition is not satisfied, where postponing refreshing the block of non-volatile memory cells is in accordance with the condition not being satisfied. In some examples, the condition evaluation component 330 may be configured as or otherwise support a means for determining, after the duration, that the condition is satisfied, where refreshing the block of non-volatile memory cells is in response to determining that the condition is satisfied.

In some examples, to support determining whether the condition of the memory system is satisfied, the condition evaluation component 330 may be configured as or otherwise support a means for determining whether a temperature associated with the memory system is within a second range of threshold temperature values. In some examples, to support determining whether the condition of the memory system is satisfied, the condition evaluation component 330 may be configured as or otherwise support a means for determining whether an operational performance of the memory system satisfies a fourth threshold value. In some examples, to support determining whether the condition of the memory system is satisfied, the condition evaluation component 330 may be configured as or otherwise support a means for determining whether the memory system is in an idle state. In some examples, to support determining whether the condition of the memory system is satisfied, the condition evaluation component 330 may be configured as or otherwise support a means for determining whether a quantity of pages of non-volatile memory cells having a respective bit error rate that satisfies the first range of threshold values satisfies a fifth threshold value.

In some examples, the page evaluation component 340 may be configured as or otherwise support a means for determining to refresh the block of non-volatile memory cells in response to determining that the bit error rate of the first page satisfies the first threshold value, where generating the second error correction code is in response to determining to refresh the block of non-volatile memory cells.

In some examples, the second error correction code is generated a second duration after generating the first error correction code. In some examples, the second duration corresponds to a difference between a first time associated with generating the first error correction code and a second time associated with determining that the bit error rate of the first page satisfies the first threshold value.

In some examples, the error correction component 325 may be configured as or otherwise support a means for generating a third error correction code associated with second data in accordance with storing the second data to a second page of non-volatile memory cells associated with the block. In some examples, the page evaluation component 340 may be configured as or otherwise support a means for determining that a second bit error rate of the second page of non-volatile memory cells fails to satisfy the first threshold value. In some examples, the error correction component 325 may be configured as or otherwise support a means for refraining from generating a fourth error correction code associated with the second data in accordance with the second bit error rate failing to satisfy the first threshold value.

In some examples, the first range of threshold values includes a second threshold value corresponding to an upper bound of the first range of threshold values. In some examples, generating the second error correction code is in accordance with the bit error rate satisfying the first threshold value.

In some examples, to support determining whether the bit error rate of the first page satisfies the first range of threshold values, the page evaluation component 340 may be configured as or otherwise support a means for determining that the bit error rate satisfies the first threshold value and that the bit error rate fails to satisfy the second threshold value, where postponing refreshing the block of non-volatile memory cells for the duration is in response to determining that the bit error rate satisfies the first threshold value and that the bit error rate fails to satisfy the second threshold value.

In some examples, to support determining whether the bit error rate of the first page satisfies the first range of threshold values, the page evaluation component 340 may be configured as or otherwise support a means for determining that the bit error rate satisfies the second threshold value. In some examples, to support determining whether the bit error rate of the first page satisfies the first range of threshold values, the block management component 335 may be configured as or otherwise support a means for refreshing, before the duration, the block of non-volatile memory cells in response to determining that the bit error rate satisfies the second threshold value.

In some examples, the second error correction code is generated at a buffer of the memory system, and the buffer management component 345 may be configured as or otherwise support a means for determining that a quantity of bits associated with a plurality of error correction codes that are stored to the buffer satisfies a third threshold value. In some examples, the second error correction code is generated at a buffer of the memory system, and the buffer management component 345 may be configured as or otherwise support a means for transferring at least the second error correction code to one or more non-volatile memory cells of the memory system in accordance with the quantity of bits stored to the buffer satisfying the third threshold value.

In some examples, the mapping management component 350 may be configured as or otherwise support a means for storing, to a volatile memory of the memory system, mapping data indicating a relationship between the second error correction code and the data stored to the first page of non-volatile memory cells in accordance with generating the second error correction code.

In some examples, the command reception component 355 may be configured as or otherwise support a means for receiving a read command for the first data stored to the first page of non-volatile memory cells. In some examples, the data access component 360 may be configured as or otherwise support a means for reading, during a second duration, the first data from the first page of non-volatile memory cells in response to receiving the read command. In some examples, the data access component 360 may be configured as or otherwise support a means for reading, during the second duration, the first error correction code and the second error correction code associated with the first data in response to receiving the read command.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

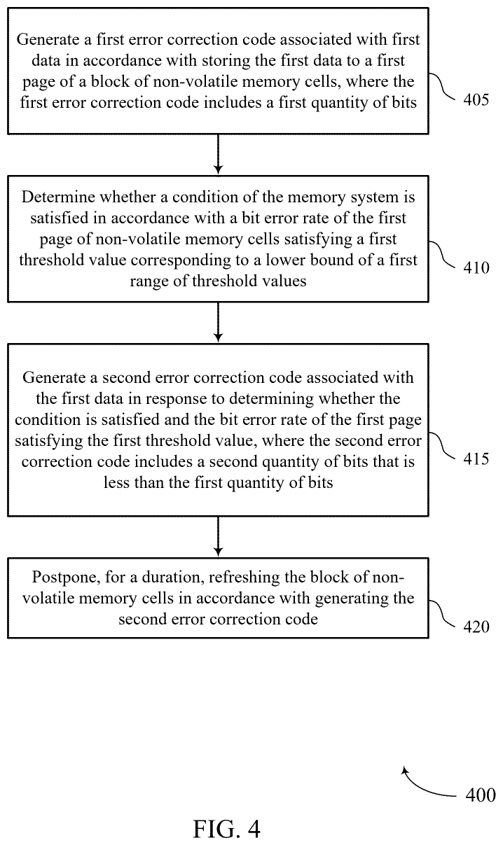

FIG. 4 shows a flowchart illustrating a method 400 that supports error correction configurations for memory systems in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include generating a first error correction code associated with first data in accordance with storing the first data to a first page of a block of non-volatile memory cells, where the first error correction code includes a first quantity of bits. In some examples, aspects of the operations of 405 may be performed by an error correction component 325 as described with reference to FIG. 3.

At 410, the method may include determining whether a condition of the memory system is satisfied in accordance with a bit error rate of the first page of non-volatile memory cells satisfying a first threshold value corresponding to a lower bound of a first range of threshold values. In some examples, aspects of the operations of 410 may be performed by a condition evaluation component 330 as described with reference to FIG. 3.

At 415, the method may include generating a second error correction code associated with the first data in response to determining whether the condition is satisfied and the bit error rate of the first page satisfying the first threshold value, where the second error correction code includes a second quantity of bits that is less than the first quantity of bits. In some examples, aspects of the operations of 415 may be performed by an error correction component 325 as described with reference to FIG. 3.

At 420, the method may include postponing, for a duration, refreshing the block of non-volatile memory cells in accordance with generating the second error correction code. In some examples, aspects of the operations of 420 may be performed by a block management component 335 as described with reference to FIG. 3.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:
Aspect 1: A method, apparatus, or non-transitory computer-readable medium including operations, features, circuitry, logic, means, or instructions, or any combination thereof for generating a first error correction code associated with first data in accordance with storing the first data to a first page of a block of non-volatile memory cells, where the first error correction code includes a first quantity of bits; determining whether a condition of the memory system is satisfied in accordance with a bit error rate of the first page of non-volatile memory cells satisfying a first threshold value corresponding to a lower bound of a first range of threshold values; generating a second error correction code associated with the first data in response to determining whether the condition is satisfied and the bit error rate of the first page satisfying the first threshold value, where the second error correction code includes a second quantity of bits that is less than the first quantity of bits; and postponing, for a duration, refreshing the block of non-volatile memory cells in accordance with generating the second error correction code.
Aspect 2: The method, apparatus, or non-transitory computer-readable medium of aspect 1, further including operations, features, circuitry, logic, means, or instructions, or any combination thereof for detecting an error in the first data and correcting the error in the first data using the first error correction code and the second error correction code.
Aspect 3: The method, apparatus, or non-transitory computer-readable medium of any of aspects 1 through 2, further including operations, features, circuitry, logic, means, or instructions, or any combination thereof for determining that the condition is satisfied and refreshing the block of non-volatile memory cells in response to determining that the condition is satisfied.
Aspect 4: The method, apparatus, or non-transitory computer-readable medium of any of aspects 1 through 3, further including operations, features, circuitry, logic, means, or instructions, or any combination thereof for determining that condition of the memory system is satisfied in accordance with a bit error rate of a second page of non-volatile memory cells satisfying the first threshold value, where the second page is associated with a second block of the memory system; refraining from postponing refreshing the second block of non-volatile memory cells for a second duration in response to determining that the condition of the memory system is satisfied; and refreshing the second block of memory cells.
Aspect 5: The method, apparatus, or non-transitory computer-readable medium of any of aspects 1 through 4, further including operations, features, circuitry, logic, means, or instructions, or any combination thereof for determining, prior to the duration, that condition is not satisfied, where postponing refreshing the block of non-volatile memory cells is in accordance with the condition not being satisfied and determining, after the duration, that the condition is satisfied, where refreshing the block of non-volatile memory cells is in response to determining that the condition is satisfied.
Aspect 6: The method, apparatus, or non-transitory computer-readable medium of any of aspects 1 through 5, where determining whether the condition of the memory system is satisfied includes operations, features, circuitry, logic, means, or instructions, or any combination thereof for determining whether a temperature associated with the memory system is within a second range of threshold temperature values; determining whether an operational performance of the memory system satisfies a fourth threshold value; determining whether the memory system is in an idle state; and determining whether a quantity of pages of non-volatile memory cells having a respective bit error rate that satisfies the first range of threshold values satisfies a fifth threshold value.
Aspect 7: The method, apparatus, or non-transitory computer-readable medium of any of aspects 1 through 6, further including operations, features, circuitry, logic, means, or instructions, or any combination thereof for determining to refresh the block of non-volatile memory cells in response to determining that the bit error rate of the first page satisfies the first threshold value, where generating the second error correction code is in response to determining to refresh the block of non-volatile memory cells.
Aspect 8: The method, apparatus, or non-transitory computer-readable medium of aspect 7, where the second error correction code is generated a second duration after generating the first error correction code and the second duration corresponds to a difference between a first time associated with generating the first error correction code and a second time associated with determining that the bit error rate of the first page satisfies the first threshold value.
Aspect 9: The method, apparatus, or non-transitory computer-readable medium of any of aspects 1 through 8, further including operations, features, circuitry, logic, means, or instructions, or any combination thereof for generating a third error correction code associated with second data in response to storing the second data to a second page of non-volatile memory cells associated with the block; determining that a second bit error rate of the second page of non-volatile memory cells fails to satisfy the first threshold value; and refraining from generating a fourth error correction code associated with the second data in accordance with the second bit error rate failing to satisfy the first threshold value.
Aspect 10: The method, apparatus, or non-transitory computer-readable medium of any of aspects 1 through 9, where the first range of threshold values includes a second threshold value corresponding to an upper bound of the first range of threshold values and generating the second error correction code is in accordance with the bit error rate satisfying the first threshold value.
Aspect 11: The method, apparatus, or non-transitory computer-readable medium of aspect 10, where determining whether the bit error rate of the first page satisfies the first range of threshold values includes operations, features, circuitry, logic, means, or instructions, or any combination thereof for determining that the bit error rate satisfies the first threshold value and that the bit error rate fails to satisfy the second threshold value, where postponing refreshing the block of non-volatile memory cells for the duration is in response to determining that the bit error rate satisfies the first threshold value and that the bit error rate fails to satisfy the second threshold value.
Aspect 12: The method, apparatus, or non-transitory computer-readable medium of any of aspects 10 through 11, where determining whether the bit error rate of the first page satisfies the first range of threshold values includes operations, features, circuitry, logic, means, or instructions, or any combination thereof for determining that the bit error rate satisfies the second threshold value, the method further including and refreshing, before the duration, the block of non-volatile memory cells in response to determining that the bit error rate satisfies the second threshold value.
Aspect 13: The method, apparatus, or non-transitory computer-readable medium of any of aspects 1 through 12, where the second error correction code is generated at a buffer of the memory system and the method, apparatuses, and non-transitory computer-readable medium further includes operations, features, circuitry, logic, means, or instructions, or any combination thereof for determining that a quantity of bits associated with a plurality of error correction codes that are stored to the buffer satisfies a third threshold value and transferring at least the second error correction code to one or more non-volatile memory cells of the memory system in accordance with the quantity of bits stored to the buffer satisfying the third threshold value.
Aspect 14: The method, apparatus, or non-transitory computer-readable medium of any of aspects 1 through 13, further including operations, features, circuitry, logic, means, or instructions, or any combination thereof for storing, to a volatile memory of the memory system, mapping data indicating a relationship between the second error correction code and the data stored to the first page of non-volatile memory cells in accordance with generating the second error correction code.
Aspect 15: The method, apparatus, or non-transitory computer-readable medium of any of aspects 1 through 14, further including operations, features, circuitry, logic, means, or instructions, or any combination thereof for receiving a read command for the first data stored to the first page of non-volatile memory cells; reading, during a second duration, the first data from the first page of non-volatile memory cells in response to receiving the read command; and reading, during the second duration, the first error correction code and the second error correction code associated with the first data in response to receiving the read command.

It should be noted that the described techniques include possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (or in conductive contact with or connected with or coupled with) one another if there is any conductive path between the components that can, at any time, support the flow of signals between the components. At any given time, the conductive path between components that are in electronic communication with each other (or in conductive contact with or connected with or coupled with) may be an open circuit or a closed circuit based on the operation of the device that includes the connected components. The conductive path between connected components may be a direct conductive path between the components or the conductive path between connected components may be an indirect conductive path that may include intermediate components, such as switches, transistors, or other components. In some examples, the flow of signals between the connected components may be interrupted for a time, for example, using one or more intermediate components such as switches or transistors.

The term “coupling” (e.g., “electrically coupling”) may refer to a condition of moving from an open-circuit relationship between components in which signals are not presently capable of being communicated between the components over a conductive path to a closed-circuit relationship between components in which signals are capable of being communicated between components over the conductive path. If a component, such as a controller, couples other components together, the component initiates a change that allows signals to flow between the other components over a conductive path that previously did not permit signals to flow.

The term “isolated” refers to a relationship between components in which signals are not presently capable of flowing between the components. Components are isolated from each other if there is an open circuit between them. For example, two components separated by a switch that is positioned between the components are isolated from each other if the switch is open. If a controller isolates two components, the controller affects a change that prevents signals from flowing between the components using a conductive path that previously permitted signals to flow.

The terms “if,” “when,” “based on,” or “based at least in part on” may be used interchangeably. In some examples, if the terms “if,” “when,” “based on,” or “based at least in part on” are used to describe a conditional action, a conditional process, or connection between portions of a process, the terms may be interchangeable.

The term “in response to” may refer to one condition or action occurring at least partially, if not fully, as a result of a previous condition or action. For example, a first condition or action may be performed, and a second condition or action may at least partially occur as a result of the previous condition or action occurring (whether directly after or after one or more other intermediate conditions or actions occurring after the first condition or action).

The devices discussed herein, including a memory array, may be formed on a semiconductor substrate, such as silicon, germanium, silicon-germanium alloy, gallium arsenide, gallium nitride, etc. In some examples, the substrate is a semiconductor wafer. In some other examples, the substrate may be a silicon-on-insulator (SOI) substrate, such as silicon-on-glass (SOG) or silicon-on-sapphire (SOP), or epitaxial layers of semiconductor materials on another substrate. The conductivity of the substrate, or sub-regions of the substrate, may be controlled through doping using various chemical species including, but not limited to, phosphorus, boron, or arsenic. Doping may be performed during the initial formation or growth of the substrate, by ion-implantation, or by any other doping means.

A switching component or a transistor discussed herein may represent a field-effect transistor (FET) and comprise a three terminal device including a source, drain, and gate. The terminals may be connected to other electronic elements through conductive materials, e.g., metals. The source and drain may be conductive and may comprise a heavily-doped, e.g., degenerate, semiconductor region. The source and drain may be separated by a lightly-doped semiconductor region or channel. If the channel is n-type (i.e., majority carriers are electrons), then the FET may be referred to as an n-type FET. If the channel is p-type (i.e., majority carriers are holes), then the FET may be referred to as a p-type FET. The channel may be capped by an insulating gate oxide. The channel conductivity may be controlled by applying a voltage to the gate. For example, applying a positive voltage or negative voltage to an n-type FET or a p-type FET, respectively, may result in the channel becoming conductive. A transistor may be “on” or “activated” if a voltage greater than or equal to the transistor's threshold voltage is applied to the transistor gate. The transistor may be “off” or “deactivated” if a voltage less than the transistor's threshold voltage is applied to the transistor gate.

The description set forth herein, in connection with the appended drawings, describes example configurations and does not represent all the examples that may be implemented or that are within the scope of the claims. The term “exemplary” used herein means “serving as an example, instance, or illustration” and not “preferred” or “advantageous over other examples.” The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Further, various components of the same type may be distinguished by following the reference label by a hyphen and a second label that distinguishes among the similar components. If just the first reference label is used in the specification, the description is applicable to any one of the similar components having the same first reference label irrespective of the second reference label.

The functions described herein may be implemented in hardware, software executed by a processing system (e.g., one or more processors, one or more controllers, control circuitry, processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The description herein is provided to enable a person skilled in the art to make or use the disclosure. Various modifications to the disclosure will be apparent to those skilled in the art, and the generic principles defined herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices; and
processing circuitry coupled with the one or more memory devices and configured to cause the memory system to:
generate a first error correction code associated with first data in accordance with storing the first data to a first page of a block of non-volatile memory cells, wherein the first error correction code comprises a first quantity of bits;
determine whether a condition of the memory system is satisfied in accordance with a bit error rate of the first page of non-volatile memory cells satisfying a first threshold value corresponding to a lower bound of a first range of threshold values;
generate a second error correction code associated with the first data in response to determining whether the condition is satisfied and the bit error rate of the first page satisfying the first threshold value, wherein the second error correction code comprises a second quantity of bits that is less than the first quantity of bits; and
postpone, for a duration, refreshing the block of non-volatile memory cells in accordance with generating the second error correction code.

2. The memory system of claim 1, wherein the processing circuitry is further configured to cause the memory system to:
detect an error in the first data; and
correct the error in the first data using the first error correction code and the second error correction code.

3. The memory system of claim 1, wherein the processing circuitry is further configured to cause the memory system to:
determine that the condition is satisfied; and
refresh the block of non-volatile memory cells in response to determining that the condition is satisfied.

4. The memory system of claim 1, wherein the processing circuitry is further configured to cause the memory system to:
determine that condition of the memory system is satisfied in accordance with a bit error rate of a second page of non-volatile memory cells satisfying the first threshold value, wherein the second page is associated with a second block of the memory system;
refrain from postponing refreshing the second block of non-volatile memory cells for a second duration in response to determining that the condition of the memory system is satisfied; and
refresh the second block of memory cells.

5. The memory system of claim 1, wherein the processing circuitry is further configured to cause the memory system to:
determine, prior to the duration, that condition is not satisfied, wherein postponing refreshing the block of non-volatile memory cells is in accordance with the condition not being satisfied; and
determine, after the duration, that the condition is satisfied, wherein refreshing the block of non-volatile memory cells is in response to determining that the condition is satisfied.

6. The memory system of claim 1, wherein the condition comprises an environmental condition of the memory system, a performance condition of the memory system, or both, and wherein, to determine whether the condition of the memory system is satisfied, the processing circuitry is configured to cause the memory system to:
determine whether a temperature associated with the memory system is within a second range of threshold temperature values;
determine whether an operational performance of the memory system satisfies a fourth threshold value;
determine whether the memory system is in an idle state; or
determine whether a quantity of pages of non-volatile memory cells having a respective bit error rate that satisfies the first range of threshold values satisfies a fifth threshold value.

7. The memory system of claim 1, wherein the processing circuitry is further configured to cause the memory system to:
determine to refresh the block of non-volatile memory cells in response to determining that the bit error rate of the first page satisfies the first threshold value, wherein generating the second error correction code is in response to determining to refresh the block of non-volatile memory cells.

8. The memory system of claim 7, wherein the second error correction code is generated a second duration after generating the first error correction code, and wherein the second duration corresponds to a difference between a first time associated with generating the first error correction code and a second time associated with determining that the bit error rate of the first page satisfies the first threshold value.

9. The memory system of claim 1, wherein the processing circuitry is further configured to cause the memory system to:
generate a third error correction code associated with second data in response to storing the second data to a second page of non-volatile memory cells associated with the block;
determine that a second bit error rate of the second page of non-volatile memory cells fails to satisfy the first threshold value; and
refrain from generating a fourth error correction code associated with the second data in accordance with the second bit error rate failing to satisfy the first threshold value.

10. The memory system of claim 1, wherein the first range of threshold values comprises a second threshold value corresponding to an upper bound of the first range of threshold values, and wherein generating the second error correction code is in accordance with the bit error rate satisfying the first threshold value.

11. The memory system of claim 10, wherein, to determine whether the bit error rate of the first page satisfies the first range of threshold values, the processing circuitry is configured to cause the memory system to:
determine that the bit error rate satisfies the first threshold value and that the bit error rate fails to satisfy the second threshold value, wherein postponing refreshing the block of non-volatile memory cells for the duration is in response to determining that the bit error rate satisfies the first threshold value and that the bit error rate fails to satisfy the second threshold value.

12. The memory system of claim 10, wherein, to determine whether the bit error rate of the first page satisfies the first range of threshold values, the processing circuitry is configured to cause the memory system to:
determine that the bit error rate satisfies the second threshold value, wherein the processing circuitry is further configured to cause the memory system to:
refresh, before the duration, the block of non-volatile memory cells in response to determining that the bit error rate satisfies the second threshold value.

13. The memory system of claim 1, wherein the second error correction code is generated at a buffer of the memory system, and the processing circuitry is further configured to cause the memory system to:
determine that a quantity of bits associated with a plurality of error correction codes that are stored to the buffer satisfies a third threshold value; and
transfer at least the second error correction code to one or more non-volatile memory cells of the memory system in accordance with the quantity of bits stored to the buffer satisfying the third threshold value.

14. The memory system of claim 1, wherein the processing circuitry is further configured to cause the memory system to:
store, to a volatile memory of the memory system, mapping data indicating a relationship between the second error correction code and the data stored to the first page of non-volatile memory cells in accordance with generating the second error correction code.

15. The memory system of claim 1, wherein the processing circuitry is further configured to cause the memory system to:
receive a read command for the first data stored to the first page of non-volatile memory cells;
read, during a second duration, the first data from the first page of non-volatile memory cells in response to receiving the read command; and
read, during the second duration, the first error correction code and the second error correction code associated with the first data in response to receiving the read command.

16. A non-transitory computer-readable medium storing code comprising instructions which, when executed by one or more processors of a memory system, cause the memory system to:
generate a first error correction code associated with first data in accordance with storing the first data to a first page of a block of non-volatile memory cells, wherein the first error correction code comprises a first quantity of bits;
determine whether a condition of the memory system is satisfied in accordance with a bit error rate of the first page of non-volatile memory cells satisfying a first threshold value corresponding to a lower bound of a first range of threshold values;
generate a second error correction code associated with the first data in response to determining whether the condition is satisfied and the bit error rate of the first page satisfying the first threshold value, wherein the second error correction code comprises a second quantity of bits that is less than the first quantity of bits; and
postpone, for a duration, refreshing the block of non-volatile memory cells in accordance with generating the second error correction code.

17. The non-transitory computer-readable medium of claim 16, wherein
the instructions, when executed by the one or more processors of the memory system, further cause the memory system to:
detect an error in the first data; and
correct the error in the first data using the first error correction code and the second error correction code.

18. The non-transitory computer-readable medium of claim 16, wherein
the instructions, when executed by the one or more processors of the memory system, further cause the memory system to:
determine that the condition is satisfied; and
refresh the block of non-volatile memory cells in response to determining that the condition is satisfied.

19. The non-transitory computer-readable medium of claim 16, wherein
the instructions, when executed by the one or more processors of the memory system, further cause the memory system to:
determine that condition of the memory system is satisfied in accordance with a bit error rate of a second page of non-volatile memory cells satisfying the first threshold value, wherein the second page is associated with a second block of the memory system;
refrain from postponing refreshing the second block of non-volatile memory cells for a second duration in response to determining that the condition of the memory system is satisfied; and
refresh the second block of memory cells.

20. The non-transitory computer-readable medium of claim 16, wherein
the instructions, when executed by the one or more processors of the memory system, further cause the memory system to:
determine, prior to the duration, that condition is not satisfied, wherein postponing refreshing the block of non-volatile memory cells is in accordance with the condition not being satisfied; and
determine, after the duration, that the condition is satisfied, wherein refreshing the block of non-volatile memory cells is in response to determining that the condition is satisfied.

21. The non-transitory computer-readable medium of claim 16, wherein
the condition comprises an environmental condition of the memory system, a performance condition of the memory system, or both, and wherein the instructions to determine whether the condition of the memory system is satisfied, when executed by the one or more processors of the memory system, cause the memory system to:
determine whether a temperature associated with the memory system is within a second range of threshold temperature values;
determine whether an operational performance of the memory system satisfies a fourth threshold value;
determine whether the memory system is in an idle state; or
determine whether a quantity of pages of non-volatile memory cells having a respective bit error rate that satisfies the first range of threshold values satisfies a fifth threshold value.

22. The non-transitory computer-readable medium of claim 16, wherein the instructions, when executed by the one or more processors of the memory system, further cause the memory system to:
determine to refresh the block of non-volatile memory cells in response to determining that the bit error rate of the first page satisfies the first threshold value, wherein generating the second error correction code is in response to determining to refresh the block of non-volatile memory cells.

23. The non-transitory computer-readable medium of claim 22, wherein
the second error correction code is generated a second duration after generating the first error correction code, and wherein the second duration corresponds to a difference between a first time associated with generating the first error correction code and a second time associated with determining that the bit error rate of the first page satisfies the first threshold value.

24. The non-transitory computer-readable medium of claim 16, wherein
the instructions, when executed by the one or more processors of the memory system, further cause the memory system to:
generate a third error correction code associated with second data in accordance with storing the second data to a second page of non-volatile memory cells associated with the block;
determine that a second bit error rate of the second page of non-volatile memory cells fails to satisfy the first threshold value; and
refrain from generating a fourth error correction code associated with the second data in accordance with the second bit error rate failing to satisfy the first threshold value.

25. A method by a memory system, comprising:
generating a first error correction code associated with first data in accordance with storing the first data to a first page of a block of non-volatile memory cells, wherein the first error correction code comprises a first quantity of bits;
determining whether a condition of the memory system is satisfied in accordance with a bit error rate of the first page of non-volatile memory cells satisfying a first threshold value corresponding to a lower bound of a first range of threshold values;
generating a second error correction code associated with the first data in response to determining whether the condition is satisfied and the bit error rate of the first page satisfying the first threshold value, wherein the second error correction code comprises a second quantity of bits that is less than the first quantity of bits; and
postponing, for a duration, refreshing the block of non-volatile memory cells in accordance with generating the second error correction code.
